(19) United States
(12) Patent Application Publication
(10) Pub. No.: US 2022/0285267 A1
(43) Pub. Date: Sep. 8, 2022

(54) FAN-OUT WAFER LEVEL PACKAGING OF SEMICONDUCTOR DEVICES

(71) Applicant: SEMICONDUCTOR COMPONENTS INDUSTRIES, LLC, Phoenix, AZ (US)

(72) Inventors: Takashi NOMA, Ota (JP); Yusheng LIN, Phoenix, AZ (US)

(73) Assignee: SEMICONDUCTOR COMPONENTS INDUSTRIES, LLC, Phoenix, AZ (US)

(21) Appl. No.: 17/249,436

(22) Filed: Mar. 2, 2021

(51) Int. Cl. H01L 23/522; H01L 23/31; H01L 25/065; H01L 23/538; H01L 23/00

(52) U.S. Cl. CPC H01L 23/5226; H01L 23/3135; H01L 23/3121; H01L 25/0655; H01L 23/5383; H01L 24/13

(57) ABSTRACT

In a general aspect, a semiconductor device assembly can include a semiconductor die having a back side and a front side, the back side being coupled with a base, the front side including active circuitry. The assembly can include a first resin encapsulation layer disposed on a first portion of the front side. The first resin encapsulation layer can be patterned to define a first opening exposing a second portion of the front side through the first resin encapsulation layer. The assembly can include a signal distribution structure that is disposed on the first resin encapsulation layer, and electrically coupled with the front side through the first opening. The assembly can include a second resin encapsulation layer disposed on a first portion of the signal distribution structure, the second resin encapsulation layer being patterned to define a second opening that exposes a second portion of the signal distribution structure.

### TECHNICAL FIELD

This description relates to packaged semiconductor devices and/or semiconductor device modules (packaged devices). More specifically, this description relates to semiconductor devices packaged in chip-scale packages, such as fan-out wafer level packages.

### BACKGROUND

Semiconductor devices (e.g., semiconductor die) can be implemented in a number of different packing configurations. For example, a semiconductor die, such as a power transistor, power diode, etc., can be included in a chip-scale package, such as fan-out wafer level package (FOWLP). However, current approaches for producing such FOWLPs packages can be cost prohibitive and/or can be susceptible to yield loss, such as cracking of, or damage to semiconductor die being included in such packages due, for example, due bonding and debonding of associated semiconductor die from carrier medium, such as wafer carriers.

### SUMMARY

In a general aspect, a semiconductor device assembly can include a semiconductor die having a back side and a front side, the back side being coupled with a base, the front side including active circuitry. The assembly can also include a first resin encapsulation layer disposed on a first portion of the front side of the semiconductor die. The first resin encapsulation layer can be patterned to define a first opening exposing a second portion of the front side of the semiconductor die through the first resin encapsulation layer. The assembly can also include a signal distribution structure that is disposed on the first resin encapsulation layer, and electrically coupled with the front side of the semiconductor die through the first opening. The assembly can further include a second resin encapsulation layer disposed on a first portion of the signal distribution structure. The second resin encapsulation layer can be patterned to define a second opening that exposes a second portion of the signal distribution structure.

In another general aspect, a semiconductor device assembly can include a semiconductor die having a back side, a front side and a plurality of edge surfaces extending between the back side and the front side. The back side of the semiconductor die can be coupled with a base including silicon, and the front side of the semiconductor die can include active circuitry. The assembly can also include a first resin encapsulation layer disposed on the base, the plurality of edge surfaces, and the front side of the front side of the semiconductor die. The first resin encapsulation layer can be patterned to define a first opening that exposes a portion of the front side of the semiconductor die through the first resin encapsulation layer. The assembly can also include a signal distribution structure that is disposed on the first resin encapsulation layer, and disposed in the first opening, such that the signal distribution structure is electrically coupled with the front side of the semiconductor die through the first opening. The assembly can also include a second resin encapsulation layer disposed on the signal distribution structure. The second resin encapsulation layer can be patterned to define a second opening that exposes a portion of the signal distribution structure. The assembly can also include a solder ball disposed in the second opening. The solder ball can be electrically coupled with the signal distribution structure.

In another general aspect, a method for producing a semiconductor device assembly can include coupling a semiconductor die with a mechanically supportive base. The semiconductor die can have a back side and a front side. The back side of the semiconductor die can be coupled with the base, and the front side of the semiconductor die can include active circuitry. The method can also include forming a first resin encapsulation layer on, at least, a first portion of the front side of the semiconductor die. The first resin encapsulation layer can be patterned to define a first opening that exposes a second portion of the front side of the semiconductor die through the first resin encapsulation layer. The method can also include forming a signal distribution structure on the first resin encapsulation layer, and in the first opening, such that the signal distribution structure is electrically coupled with the front side of the semiconductor die. The method can also include forming a second resin encapsulation layer on, at least, a first portion of the signal distribution structure. The second resin encapsulation layer can be patterned to define a second opening that exposes a second portion of the signal distribution structure.

### BRIEF DESCRIPTION OF THE DRAWINGS

FIG. 1 is a diagram that illustrates a side, cross-sectional view of a fan-out wafer level package (FOWLP)

FIG. 2 is a diagram that schematically illustrates a plan view of a FOWLP.

FIGS. 3A-3E are diagrams that illustrate a process flow for producing a FOWLP, such as the FOWLP.

FIG. 4 is a diagram that schematically illustrates another plan view of a FOWLP.

FIGS. 5-10 are diagrams illustrating various encapsulation layer arrangements that can be included in a FOWLP, such as FOWLPs produced using the process flow of FIGS. 3A-3E, or as alternatives to the approaches of the process flow of FIGS. 3A-3E.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings, but are provided for context between related views. Also, not all like elements in the drawings are specifically referenced with a reference symbol when multiple instances of an element are illustrated.

### DETAILED DESCRIPTION

This disclosure relates to packaged semiconductor device apparatus (semiconductor device assemblies) and associated methods of manufacturing packaged semiconductor devices. More specifically, this disclosure relates to fan-out wafer level packages (FOWLPs) for packaging semiconductor devices (semiconductor die), and associated manufacturing processes. In the approaches described herein, a FOWLP can include one or more patterned resin encapsulation layers, which, in some implementations, can be included in place of molding compound layers that are formed using molding jigs or appliances. The FOWLPs and manufacturing approaches disclosed herein can have reduced manufacturing cost, due to reducing a number of processing operations and/reducing the tooling and/or equipment used to produce a FOWLP. Also, the approaches described herein can reduce yield loss during manufacturing, as compared to current FOWLP implementations.

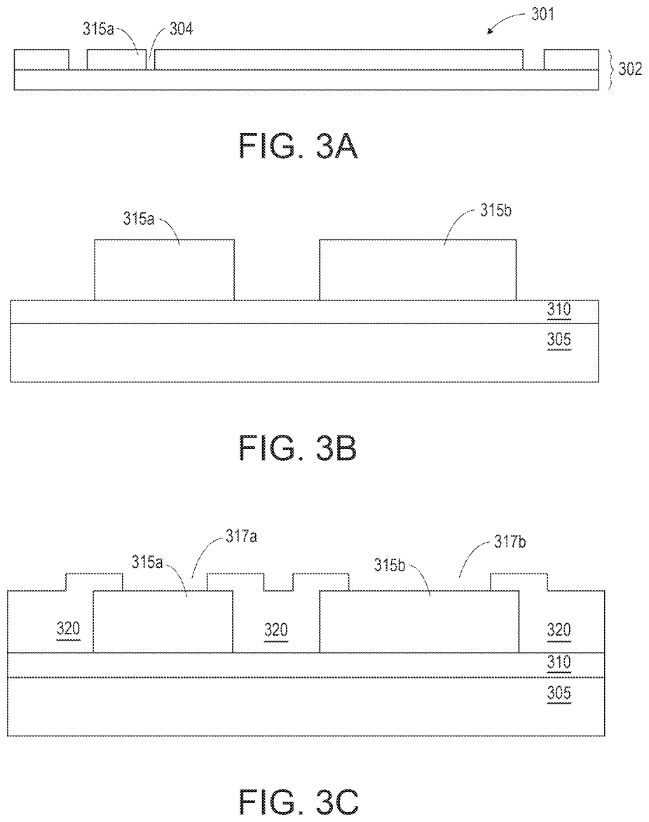

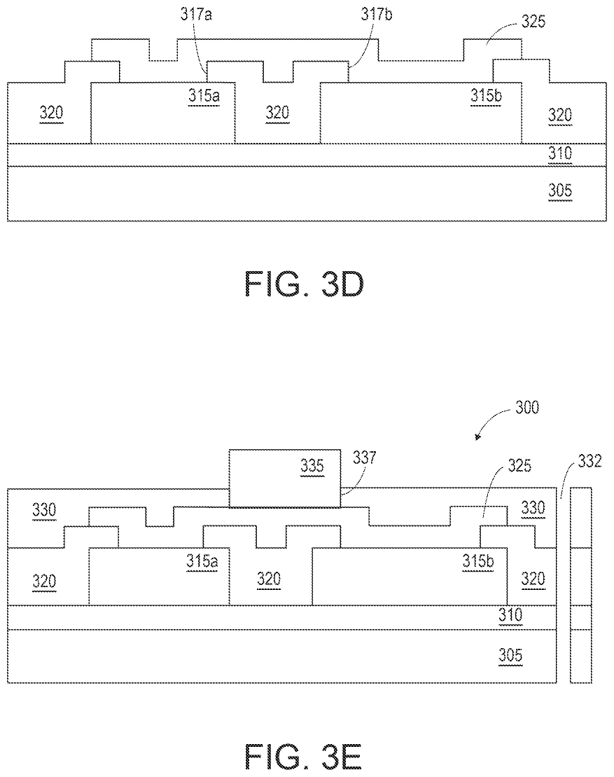

For instance, the approaches described herein can reduce a number of assembly process operations for producing a FOWLP by over 30-percent. For instance in some implementations, a number of assembly process operations can be reduced from nineteen operations to thirteen operations. In some implementations, molding operations are not included, which can reduce tooling cost, and/or processing cost. Such an example process is illustrated below with respect to FIGS. 3A-3E. In some implementations, a FOWLP can include a pre-molded (e.g., compression molded, injection molded, etc.) structure that includes one or more cavities formed in a molding compound, where respective semiconductor die can be disposed in the cavities.

Also, in the example implementations described herein, semiconductor die included in a FOWLP are not repeatedly bonded and debonded, e.g., from support and/or carrying medium, nor are the semiconductor die mounted on a support structure on a side including active circuitry, such as a power transistor, an integrated circuit, and so forth. Accordingly, yield loss associated with such process operations, e.g., due to damage to the semiconductor die, can be reduced and/or eliminated. Additionally, in such example approaches, the use of equipment for bonding and debonding can be eliminated, which can further reduce processing cost.

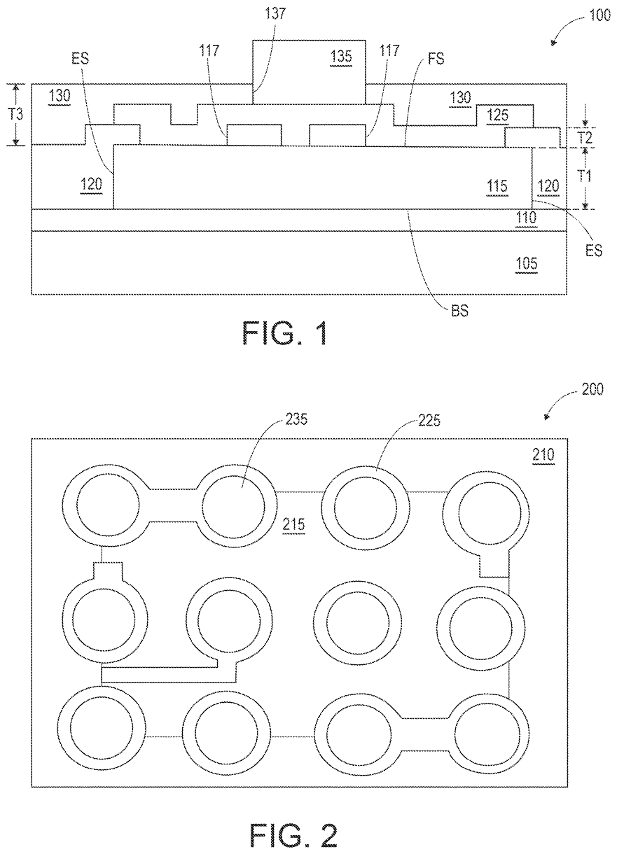

FIG. 1 is a diagram that illustrates a side, cross-sectional view of a fan-out wafer level package (FOWLP) 100. The cross-sectional view of FIG. 1, as well as other cross-sectional view described below, can be taken through a solder ball of a ball-grid array included in then FOWLP 100. While only a single solder ball is shown in FIG. 1, in some implementations, a plurality of solder balls can be included.

As can be seen in FIG. 1, the FOWLP 100 includes a base 105, a die attach layer 110, a semiconductor die 115, a first resin encapsulation layer 120, a signal distribution structure 125, a second resin encapsulation layer 130 and a solder ball 135. In some implementations, the FOWLP 100 can be produced using a process that is similar to the process illustrated in FIGS. 3A-3E and discussed below. Various dimensions are referenced in FIG. 1. These dimensions are given be way of example, and for purposes of illustration. Similar elements in other example implementations described herein can have similar dimensions. However, for purpose of brevity, such dimensions may be not described with respect to each example implementation.

In the FOWLP 100, the base 105 can include a portion of a silicon support wafter, to which the semiconductor die 115 is coupled using the die attach layer 110. In some implementations, the base 105 can include other materials, such as glass, ceramic, plastic, metal, tape, etc. In some implementations, the die attach layer 110 can be an adhesive, a tape, or a die attach film. While FIG. 1 illustrates the die attach layer 110 as being continuously disposed over an upper surface of the base 105, in some implementations the die attach layer 110 can just be disposed between the semiconductor die 115 and the base 105, e.g., and not laterally extend from the semiconductor die 115 on the base 105. In example implementations, a base can provide a structural foundation for formation of, e.g., a FOWLP. That is a material used for such a base can implement, or provide a structural base for FOWLP implementations.

As shown in FIG. 1, the semiconductor die 115 has a front side FS, a back side BS and edge surface ES, e.g., four edge surfaces or side surfaces. In this example, the front side FS can include active circuitry, the back side BS can be a back-ground surface of a semiconductor substrate, and the edge surfaces ES, or side surfaces of the semiconductor die 115 can extend between the front side FS and the back side BS. In the FOWLP 100, the semiconductor die 115 has a thickness of T1, which can be on the order of 100 micrometers (μm) or less. As noted above, the semiconductor die 115 can be thinned using a back side grinding operation, e.g., which can be performed at wafer level (prior to dicing an associated semiconductor wafer into individual semiconductor die), to achieve the desired thickness T1.

In the FOWLP 100, the first resin encapsulation layer 120 can be, at least in part, disposed on the die attach layer 110, or could be directly disposed on the base 105 in implementations where the die attach layer 110 does not continuously extend over the surface of the base 105. As also shown in FIG. 1, the first resin encapsulation layer 120 can have a portion with a thickness T2 that is disposed on the front side FS of the semiconductor die 115. Depending on the particular implementation, the thickness T2 can be in a range of 1 μm to 100 μm. In some implementations, the first resin encapsulation layer 120 can include solder resist, e.g., a patterned polymer layer, or other patterned resin layer. In some implementations, the first resin encapsulation layer 120 can be patterned using a screening operation, such as silk screening, or can be patterned using photolithography and/or etching operations. Depending on the particular implementation, the first resin encapsulation layer 120 can be cured using a bake operation, or can be applied as a viscous material including a curing agent. As shown in FIG. 1, the first resin encapsulation layer 120 can be patterned to include one or more openings 117, through which the front side of the semiconductor die 115 is exposed.

As shown in FIG. 1, the signal distribution structure 125 of the FOWLP 100 can be disposed on the first resin encapsulation layer 120 and in the one or more openings 117, such that the signal distribution structure 125 is electrically coupled with active circuitry included on the front side FS of the semiconductor die 115, e.g., electrically and mechanically coupled with signal pads on the semiconductor die 115. In some implementations, such as the example of FIG. 1, the signal distribution structure 125 can distribute (fan-out) signals from the semiconductor die 115. In some implementations, the signal distribution structure 125 can include a patterned cooper layer that is disposed on a barrier metal layer, such as a sputtered titanium-copper layer. The barrier metal layer can be referred to as under-bump metallization and can facilitate formation of a low resistance electrical contact, prevent material diffusion between the patterned copper layer and signal pads of the semiconductor die 115, and/or facilitate a mechanical connection between the signal distribution structure 125 and the signal pads.

In this example, the second resin encapsulation layer 130 of the FOWLP 100 is disposed on the first resin encapsulation layer 120 and the signal distribution structure 125, and includes an opening 137 that is patterned in the second resin encapsulation layer 130. The second resin encapsulation layer 130 can have a thickness T3, which can be in a range of 1 μm to 100 μm. The opening 137 can expose a portion of the signal distribution structure 125 through the second resin encapsulation layer 130. As shown in FIG. 1, the solder ball 135 can be disposed in the opening 137 and on the exposed portion of the signal distribution structure 125, and can be electrically coupled with the signal distribution structure 125.

FIG. 2 is a diagram that schematically illustrates a plan view of a FOWLP 200, which can be an implementation of the FOWLP 100 (e.g., with a modified signal distribution structure). For purposes of illustration, resin encapsulation layers of the FOWLP 200, such as the first resin encapsulation layer 120 and the second resin encapsulation layer 130 of the FOWLP 100, are not shown in FIG. 2, so as not obscure the arrangement of the other elements.

As shown in FIG. 2, the FOWLP 200 includes a semiconductor die 215 that is disposed on a die attach layer 210. As with the die attach layer 110 of the FOWLP 100, the die attach layer 210 can be disposed on a base, e.g., a portion of a silicon wafer and/or other material, and can include an adhesive, a tape, and/or a die attach film. The FOWLP 200 also includes a signal distribution structure 225 that can fan out signals from signal pads of the semiconductor die 215. The FOWLP 200 can also include a ball-grid array that includes a plurality of solder balls 235 that are disposed on the signal distribution structure 225 (e.g., in openings of a resin encapsulation layer), and provide electrical connections to the semiconductor die 215.

FIGS. 3A-3E are diagrams that illustrate a process flow for producing a FOWLP 300, as shown in FIG. 3E. That is, the process of FIGS. 3A-3E illustrates an assembly method for producing a FOWLP with multiple semiconductor die. As indicated above, the FOWLP 100 (or the FOWLP 200) can be produced using a processing flow that is similar to the processing flow of FIGS. 3A-3E for producing the FOWLP 300.

Referring to FIG. 3A, a back-ground (thinned) wafer 301 can be mounted on, or coupled to a wafer a carrier 302, which include be a wafer dicing tape or other carrier medium. The wafer 301 can then be singulated by cutting the wafer 301 to form openings 304, which separates the semiconductor die 315a from the wafer 301. In some implementations, the wafer 301 can be cut, or singulated, using a saw, a laser, or a plasma cutter. Referring to FIG. 3B, the semiconductor die 315a (and a semiconductor die 315b) can be removed from the carrier 302 and coupled with a base 305, such as those described above, using a die attach layer 310. In some implementations, the semiconductor die 315b can be singulated from a same wafer as the semiconductor die 315a, or can be singulated from a different semiconductor wafer that is similarly mounted a carrier and singulated. The die attach layer 310 can include an adhesive, a tape, and/or a die attach film.

Referring to FIG. 3C, a first resin encapsulation layer 320 can be formed, where the first resin encapsulation layer 320 is disposed on the die attach layer 310, on respective edge surfaces of the semiconductor die 315a and the semiconductor die 315b, and on respective front sides of the semiconductor die 315a and the semiconductor die 315b. As shown in FIG. 3C, the first resin encapsulation layer 320 can be patterned to include an opening 317a that exposes a portion of the semiconductor die 315a, and an opening 317b that exposes a portion of the semiconductor die 315b. The first resin encapsulation layer 320 can be implemented using the approaches described herein. For instance, the first resin encapsulation layer 320 can include one or more of a printed resin layer, a solder resist layer, and/or a dispensed resin layer.

Referring to FIG. 3D, a signal distribution structure 325 is formed on the first resin encapsulation layer 320, in the opening 317a, and in the opening 317b. In this example, the signal distribution structure 325 is electrically coupled with active circuitry of the semiconductor die 315a and active circuitry of the semiconductor die 315b, and electrically couples the semiconductor die 315a with the semiconductor die 315b. In some implementations, forming the signal distribution structure 325 can include sputtering a barrier metal over the exposed portion of the semiconductor die 315a, the exposed portion of the semiconductor die 315b, and the first resin encapsulation layer 320. A photoresist mask can then be formed to define where copper, or other conductive material is to be patterned, such as shown in FIG. 3D. A plating operation can then be performed to form copper, or other conductive material portions of the signal distribution structure 325. After the plating operation, an etch can be performed to remove the photoresist masked and barrier metal in areas where plated material was not formed (e.g., barrier metal that was disposed under the photoresist mask).

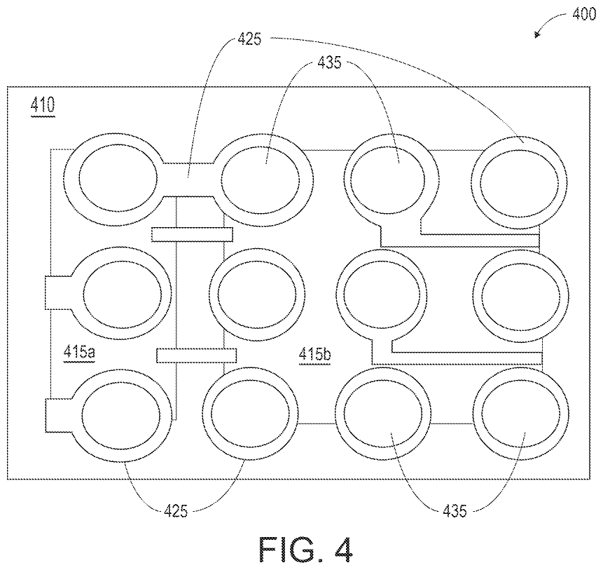

Referring to FIG. 3E, a second resin encapsulation layer 330 can be formed, where the second resin encapsulation layer 330 is disposed on the first resin encapsulation layer 320, and on the signal distribution structure 325. As shown in FIG. 3E, the second resin encapsulation layer 330 can be patterned to include an opening 337 that exposes a portion of the signal distribution structure 325. The second resin encapsulation layer 330 can be implemented using the approaches described herein. For instance, the second resin encapsulation layer 330 can include one or more of a printed resin layer, a solder resist layer, and/or a dispensed resin layer. As also shown in FIG. 3E, a solder ball 335 can be formed in the opening 337, and can be disposed on, and electrically coupled with the signal distribution structure 325. While only a single solder ball 335 is shown in FIG. 3E, in some implementations, such as the example of FIG. 4, a plurality of solder balls can be included in the FOWLP 300. As is also shown in FIG. 3E, the FOWLP 300 can be singulated, e.g., from other FOWLPs, by cutting openings 332 to define a perimeter of the FOWLP 300. In some implementations, the openings 332 can be formed using a saw, a laser, or a plasma cutter.

FIG. 4 is a diagram that schematically illustrates another plan view of a FOWLP 400, which can be an implementation of the FOWLP 300 (e.g., with a modified signal distribution structure). For purposes of illustration, as with the FOWLP 200 illustrated in FIG. 2, resin encapsulation layers of the FOWLP 400, such as the first resin encapsulation layer 320 and the second resin encapsulation layer 330 of the FOWLP 300, are not shown in FIG. 4, so as not obscure the arrangement of the other elements.

As shown in FIG. 4, the FOWLP 400 includes a semiconductor die 415a and a semiconductor die 415b, which are both disposed on a die attach layer 410. As with the die attach layer 310 of the FOWLP 300, the die attach layer 410 can be disposed on a base, e.g., a portion of a silicon wafer and/or other material, and can include an adhesive, a tape, and/or a die attach film. The FOWLP 400 also includes a signal distribution structure 425 that can fan out signals from signal pads of the semiconductor die 415a and 415b, as well as electrically couple the semiconductor die 415a with the semiconductor 415b. The FOWLP 400 can also include a ball-grid array that includes a plurality of solder balls 435 that are disposed on the signal distribution structure 425 (e.g., in openings of a resin encapsulation layer), and provide respective electrical connections to the semiconductor die 415a and 415b.

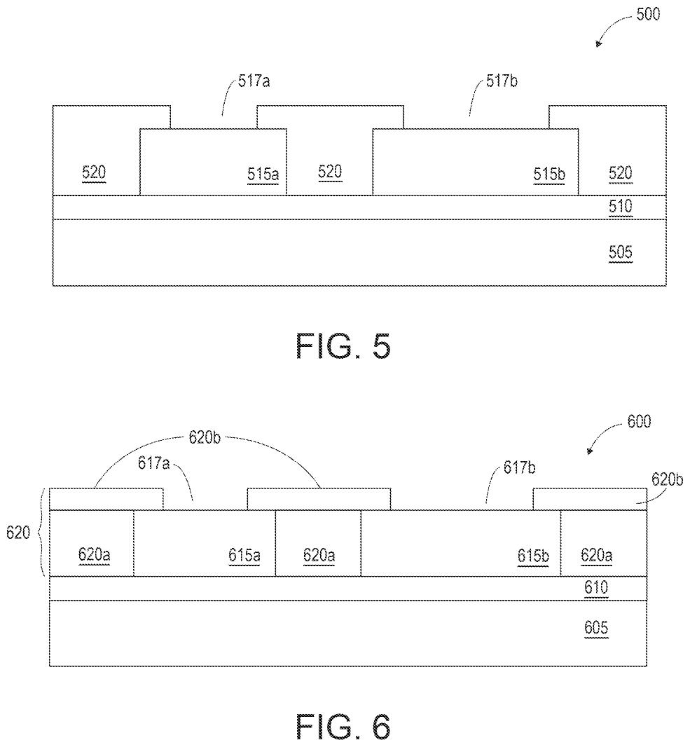

FIGS. 5-10 are diagrams illustrating various encapsulation layer arrangements that can be included in a FOWLP, such as FOWLPs produced using the process flow of FIGS. 3A-3E, or as alternatives to the approaches of the process flow of FIGS. 3A-3E. In FIGS. 5-10, the illustrated implementations are FOWLPs prior to formation of a signal distribution layer. In some implementations, the arrangements shown in FIGS. 5-10 can be further processed, such as described with respect to FIGS. 3D and 3E, e.g., to form signal distribution layer, another encapsulation layer, and a ball-grid array. Also, some elements in FIGS. 5-10, such as those that are similar to, or are the same as elements of the FOWLPs 100, 200, 300 and 400, are not described in detail again with respect to FIGS. 5-10.

Referring to FIG. 5, a FOWLP 500 is shown that includes a base 505, a die attach layer 510, a semiconductor die 515a, a semiconductor die 515b, and a resin encapsulation layer 520. In this example, the resin encapsulation layer 520 can include a printed resin layer. For instance, in some implementations, the first resin encapsulation layer 520 can be formed using 3-dimensional (3D) printing. The resin encapsulation layer 520 can be disposed on the die attach layer 510, on edges surfaces of the semiconductor die 515a and the semiconductor die 515b, and on front sides of the semiconductor die 515a and the semiconductor die 515b. In this example, 3D printing the resin encapsulation layer 520 can include defining openings 517a and 517b, through which respective portions of the semiconductor die 515a and the semiconductor die 515b are exposed, e.g., for contact with a later-formed signal distribution structure.

Referring to FIG. 6, a FOWLP 600 is shown that includes a base 605, a die attach layer 610, a semiconductor die 615a, a semiconductor die 615b, and a resin encapsulation layer 620. In this example, the resin encapsulation layer 620 includes a dispensed resin layer 620a that is disposed on the die attach layer 610 and edge surfaces of the semiconductor die 615a and the semiconductor die 615b. In some implementations, a viscous resin can be dispensed for the dispensed resin layer 620a, as shown in FIG. 6, and then cured. Curing of the dispensed resin layer 620a can be achieved using a bake operation and/or a curing agent included in the viscous resin. As further shown in FIG. 6, the resin encapsulation layer 620 can also include a patterned resin layer 620b, that can include a solder resist layer, as an example. In this example, the 620b can be disposed on the dispensed resin layer 620a, a front side of the semiconductor die 615a, and a front side of the semiconductor die 615b. The patterned resin layer 620b can be patterned to define openings 617a and 617b, through which respective portions of the semiconductor die 615a and the semiconductor die 615b are exposed, e.g., for contact with a later-formed signal distribution structure.

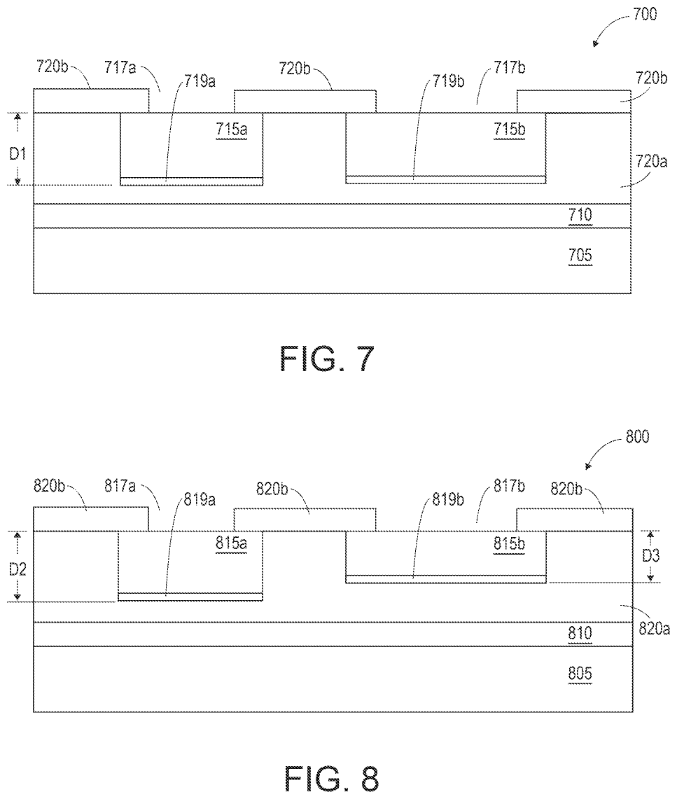

FIGS. 7-10 illustrate example FOWLP implementation including a first encapsulation layer that includes a pre-molded structure and a second encapsulation layer that includes a resin encapsulation layer, such as the resin encapsulation layers described herein. In the implementations of FIGS. 7-10, the respective pre-molded structures can include an epoxy molding compound structure (e.g., compression molded, injection molded, transfer molded, etc.), where the molding compound structure includes one or more cavities, or recesses defined therein, in which one or more semiconductor die can be disposed.

Referring to FIG. 7, a FOWLP 700 is shown that includes a base 705, a die attach layer 710, a pre-molded structure 720a, a semiconductor die 715a disposed in a first recess of the pre-molded structure 720a, a semiconductor die 715b disposed in a second recess of the pre-molded structure 720a, and a resin encapsulation layer 720b. As shown in FIG. 7, the pre-molded structure 720a can be coupled with the base 705 via the die attach layer 710. In the FOWLP 700, the semiconductor die 715a can be coupled with the pre-molded structure 720a in the first recess using a first adhesive layer 719a, while the semiconductor die 715b can be coupled with the pre-molded structure 720a in the second recess using a second adhesive layer 719b. In this example, the semiconductor die 715a and the semiconductor die 715b can of a same thickness and their respective recesses can be of a same depth D1, where D1 can be in range of 1 μm to 200 μm. As shown in FIG. 7, the front side surfaces of the semiconductor die 715a and the semiconductor die 715b can be coplanar with (flush with) an upper surface of the pre-molded structure 720a. The resin encapsulation layer 720b can be patterned to define openings 717a and 717b, through which respective portions of the semiconductor die 715a and the semiconductor die 715b are exposed, e.g., for contact with a later-formed signal distribution structure.

Referring to FIG. 8, a FOWLP 800 is shown that includes a base 805, a die attach layer 810, a pre-molded structure 820a, a semiconductor die 815a disposed in a first recess of the pre-molded structure 820a, a semiconductor die 815b disposed in a second recess of the pre-molded structure 820a, and a resin encapsulation layer 820b. As shown in FIG. 8, the pre-molded structure 820a can be coupled with the base 805 via the die attach layer 810. In the FOWLP 800, the semiconductor die 815a can be coupled with the pre-molded structure 820a in the first recess using a first adhesive layer 819a, while the semiconductor die 815b can be coupled with the pre-molded structure 820a in the second recess using a second adhesive layer 819b. In this example, the semiconductor die 815a and the semiconductor die 815b can be of different thicknesses and their respective recesses can be of different depths, respectively depth D2 and depth D3. As shown in FIG. 8, the depths D2 and D3 can be selected such that the front side surfaces of the semiconductor die 815a and the semiconductor die 815b are coplanar with (flush with) an upper surface of the pre-molded structure 820a. In some implementations, the depth D2 can be in a range of 1 μm to 200 μm, while the depth D3 can be in a range of 1 μm to 150 μm. The patterned resin layer 820b can be patterned to define openings 817a and 817b, through which respective portions of the semiconductor die 815a and the semiconductor die 815b are exposed, e.g., for contact with a later-formed signal distribution structure.

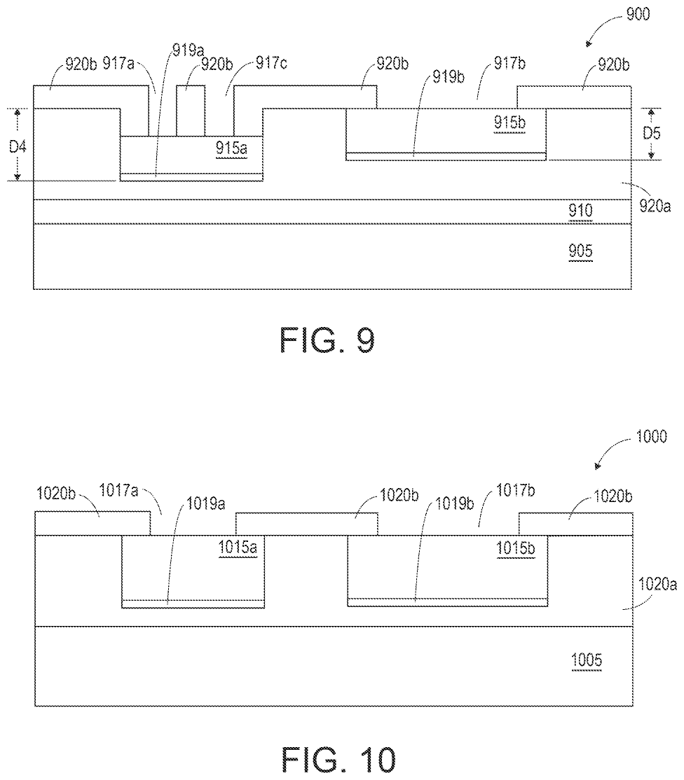

Referring to FIG. 9, a FOWLP 900 is shown that includes a base 905, a die attach layer 910, a pre-molded structure 920a, a semiconductor die 915a disposed in a first recess of the pre-molded structure 920a, a semiconductor die 915b disposed in a second recess of the pre-molded structure 920a, and a resin encapsulation layer 920b. As shown in FIG. 9, the pre-molded structure 920a can be coupled with the base 905 via the die attach layer 910. In the FOWLP 900, the semiconductor die 915a can be coupled with the pre-molded structure 920a in the first recess using a first adhesive layer 919a, while the semiconductor die 915b can be coupled with the pre-molded structure 920a in the second recess using a second adhesive layer 919b. In this example, the semiconductor die 915a and the semiconductor die 915b can of a same thickness, and their respective recesses in the pre-molded structure 920a can be of different depths, respectively depth D4 and D5. As shown in FIG. 9, the depths D4 and D5 can be selected such that the front side surface of the semiconductor die 915a is recessed from an upper surface of the pre-molded structure 920a, and the front side surface of the semiconductor die 815b is coplanar with (flush with) an upper surface of the pre-molded structure 920a. In some implementations, the depth D4 can be in a range of 1 μm to 200 μm, while the depth D5 can be in a range of 1 μm to 150 μm. The resin encapsulation layer 920b can be patterned to define openings 917a, 917b and 917c, through which respective portions of the semiconductor die 915a and the semiconductor 9ie 815b are exposed, e.g., for contact with a later-formed signal distribution structure. As also shown in FIG. 9, in this example implementation portions of the resin encapsulation layer 920b can extend into the recess in which the semiconductor die 915a is disposed, e.g., to define the openings 917a and 917c.

Referring to FIG. 10, a FOWLP 1000 is shown that is similar to the FOWLP 700, but excludes the die attach layer 710. That is, the FOWLP 1000 includes a base 1005, a pre-molded structure 1020a that is formed directly on the base 1005, a semiconductor die 1015a disposed in a first recess of the pre-molded structure 1020a, a semiconductor die 1015b disposed in a second recess of the pre-molded structure 1020a, and a resin encapsulation layer 1020b. In the FOWLP 1000, the semiconductor die 1015a can be coupled with the pre-molded structure 1020a in the first recess using a first adhesive layer 1019a, while the semiconductor die 1015b can be coupled with the pre-molded structure 1020a in the second recess using a second adhesive layer 1019b. In this example, as with the FOWLP 700, the semiconductor die 1015a and the semiconductor die 1015b are of a same thickness and their respective recesses can be of a same depth, e.g., depth D1 in FIG. 7. As shown in FIG. 10, the front side surfaces of the semiconductor die 1015a and the semiconductor die 1015b are coplanar with (flush with) an upper surface of the pre-molded structure 1020a. The resin encapsulation layer 1020b can be patterned to define openings 1017a and 1017b, through which respective portions of the semiconductor die 1015a and the semiconductor die 1015b are exposed, e.g., for contact with a later-formed signal distribution structure. In some implementations, the recesses in the pre-molded structure 1020a can extend through to the base 1005. In such implementations, one, or both of the semiconductor die 1015a and the 1015b can be disposed on (directly disposed on) the base 1005 (and coupled to base 1005 with respective adhesive layers 1019a and 1019b). In some implementations, a thickness of the pre-molded structure 1020a can be adjusted so as to establish a desired orientation of the front sides of the semiconductor die 1015a and the semiconductor die 1015b with the upper surface of the pre-molded structure 1020a.

In a general aspect, a semiconductor device assembly can include a semiconductor die having a back side and a front side, the back side being coupled with a base, the front side including active circuitry. The assembly can also include a first resin encapsulation layer disposed on a first portion of the front side of the semiconductor die. The first resin encapsulation layer can be patterned to define a first opening exposing a second portion of the front side of the semiconductor die through the first resin encapsulation layer. The assembly can also include a signal distribution structure that is disposed on the first resin encapsulation layer, and electrically coupled with the front side of the semiconductor die through the first opening. The assembly can further include a second resin encapsulation layer disposed on a first portion of the signal distribution structure. The second resin encapsulation layer can be patterned to define a second opening that exposes a second portion of the signal distribution structure.

Implementations can include one or more of the following features. For example, the first resin encapsulation layer can include a first solder resist layer. The second resin encapsulation layer can include a second solder resist layer. The first resin encapsulation layer can also include a dispensed resin layer. The dispensed resin layer can be disposed between the base and the first solder resist layer. The first resin encapsulation layer can include a printed resin layer, and the second resin encapsulation layer can include a solder resist layer.

The semiconductor die can be a first semiconductor die. The semiconductor device assembly can include a second semiconductor die disposed on the base. The signal distribution structure can electrically couple the active circuitry of the first semiconductor die with active circuitry included in the second semiconductor die.

The base can include at least one of silicon or glass. The base can include molding compound. The semiconductor die can being disposed in a recess defined in the molding compound. The base can include silicon. The molding compound can be disposed on the silicon.

The semiconductor device assembly can include a solder ball disposed in the second opening. The solder ball can be electrically coupled with the signal distribution structure. The solder ball can be a first solder ball. The semiconductor assembly can include a second solder ball that is disposed in a third opening that exposes a third portion of the signal distribution structure. The second solder ball can being electrically coupled with the signal distribution structure.

The first resin encapsulation layer can encapsulate a plurality of edges surfaces of the semiconductor die. The plurality of edge surfaces can be disposed between the back side of the semiconductor die and the front side of the semiconductor die.

In another general aspect, a semiconductor device assembly can include a semiconductor die having a back side, a front side and a plurality of edge surfaces extending between the back side and the front side. The back side of the semiconductor die can be coupled with a base including silicon, and the front side of the semiconductor die can include active circuitry. The assembly can also include a first resin encapsulation layer disposed on the base, the plurality of edge surfaces, and the front side of the front side of the semiconductor die. The first resin encapsulation layer can be patterned to define a first opening that exposes a portion of the front side of the semiconductor die through the first resin encapsulation layer. The assembly can also include a signal distribution structure that is disposed on the first resin encapsulation layer, and disposed in the first opening, such that the signal distribution structure is electrically coupled with the front side of the semiconductor die through the first opening. The assembly can also include a second resin encapsulation layer disposed on the signal distribution structure. The second resin encapsulation layer can be patterned to define a second opening that exposes a portion of the signal distribution structure. The assembly can also include a solder ball disposed in the second opening. The solder ball can be electrically coupled with the signal distribution structure.

Implementations can include one or more of the following features. For example, the semiconductor die can be coupled with the structure using at least one of an adhesive, a tape, or a die attach film. The first resin encapsulation layer can include a first solder resist layer. The second resin encapsulation layer can include a second solder resist layer. The first resin encapsulation layer can include a dispensed resin layer. The dispensed resin layer can be disposed between the base and the first solder resist layer. The first resin encapsulation layer can include a printed resin layer, and the second resin encapsulation layer can include a solder resist layer.

In another general aspect, a method for producing a semiconductor device assembly can include coupling a semiconductor die with a mechanically supportive base. The semiconductor die can have a back side and a front side. The back side of the semiconductor die can be coupled with the base, and the front side of the semiconductor die can include active circuitry. The method can also include forming a first resin encapsulation layer on, at least, a first portion of the front side of the semiconductor die. The first resin encapsulation layer can be patterned to define a first opening that exposes a second portion of the front side of the semiconductor die through the first resin encapsulation layer. The method can also include forming a signal distribution structure on the first resin encapsulation layer, and in the first opening, such that the signal distribution structure is electrically coupled with the front side of the semiconductor die. The method can also include forming a second resin encapsulation layer on, at least, a first portion of the signal distribution structure. The second resin encapsulation layer can be patterned to define a second opening that exposes a second portion of the signal distribution structure.

Implementations can include one or more of the following features. For example, the semiconductor die can be a first semiconductor die. The method can include coupling a second semiconductor die with the base. The signal distribution structure can electrically couple the active circuitry of the first semiconductor die with active circuitry included in the second semiconductor die.

Forming the first resin encapsulation layer can include forming a first solder resist layer. Forming the second resin encapsulation layer can include forming a second solder resist layer. Forming the first resin encapsulation layer can include forming a printed resin layer. Forming the second resin encapsulation layer can include forming a solder resist layer.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, Silicon (Si), Gallium Arsenide (GaAs), Gallium Nitride (GaN), and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device assembly, comprising:
a semiconductor die having a back side and a front side, the back side being coupled with a base, the front side including active circuitry;
a first resin encapsulation layer disposed on a first portion of the front side of the semiconductor die, the first resin encapsulation layer being patterned to define a first opening exposing a second portion of the front side of the semiconductor die through the first resin encapsulation layer;
a signal distribution structure:
disposed on the first resin encapsulation layer; and
electrically coupled with the front side of the semiconductor die through the first opening; and
a second resin encapsulation layer disposed on a first portion of the signal distribution structure, the second resin encapsulation layer being patterned to define a second opening that exposes a second portion of the signal distribution structure.

2. The semiconductor device assembly of claim 1, wherein:
the first resin encapsulation layer includes a first solder resist layer; and
the second resin encapsulation layer includes a second solder resist layer.

3. The semiconductor device assembly of claim 2, wherein the first resin encapsulation layer further includes a dispensed resin layer,
the dispensed resin layer being disposed between the base and the first solder resist layer.

4. The semiconductor device assembly of claim 1, wherein:
the first resin encapsulation layer includes a printed resin layer; and
the second resin encapsulation layer includes a solder resist layer.

5. The semiconductor device assembly of claim 1, wherein the semiconductor die is a first semiconductor die, the semiconductor device assembly further comprising:
a second semiconductor die disposed on the base, the signal distribution structure electrically coupling the active circuitry of the first semiconductor die with active circuitry included in the second semiconductor die.

6. The semiconductor device assembly of claim 1, wherein the base includes at least one of silicon, glass, ceramic, plastic, metal or tape.

7. The semiconductor device assembly of claim 1, wherein the base includes molding compound, the semiconductor die being disposed in a recess defined in the molding compound.

8. The semiconductor device assembly of claim 7, wherein the base further includes silicon, the molding compound being disposed on the silicon.

9. The semiconductor device assembly of claim 1, further comprising a solder ball disposed in the second opening, the solder ball being electrically coupled with the signal distribution structure.

10. The semiconductor device assembly of claim 9, the solder ball being a first solder ball, the semiconductor device assembly further comprising a second solder ball that is disposed in a third opening that exposes a third portion of the signal distribution structure, the second solder ball being electrically coupled with the signal distribution structure.

11. The semiconductor device assembly of claim 1, wherein the first resin encapsulation layer encapsulates a plurality of edges surfaces of the semiconductor die, the plurality of edge surfaces being disposed between the back side of the semiconductor die and the front side of the semiconductor die.

12. A semiconductor device assembly, comprising:
a semiconductor die having a back side, a front side and a plurality of edge surfaces extending between the back side and the front side, the back side being coupled with a base including silicon, the front side including active circuitry;
a first resin encapsulation layer disposed on the base, the plurality of edge surfaces, and the front side of the front side of the semiconductor die, the first resin encapsulation layer being patterned to define a first opening that exposes a portion of the front side of the semiconductor die through the first resin encapsulation layer;
a signal distribution structure:
disposed on the first resin encapsulation layer; and
disposed in the first opening, such that the signal distribution structure is electrically coupled with the front side of the semiconductor die through the first opening;
a second resin encapsulation layer disposed on the signal distribution structure, the second resin encapsulation layer being patterned to define a second opening that exposes a portion of the signal distribution structure; and
a solder ball disposed in the second opening, the solder ball being electrically coupled with the signal distribution structure.

13. The semiconductor device assembly of claim 12, wherein the semiconductor die is coupled with the base using at least one of:
an adhesive;
a tape; or
a die attach film.

14. The semiconductor device assembly of claim 12, wherein:
the first resin encapsulation layer includes a first solder resist layer; and
the second resin encapsulation layer includes a second solder resist layer.

15. The semiconductor device assembly of claim 14, wherein the first resin encapsulation layer further includes a dispensed resin layer,
the dispensed resin layer being disposed between the base and the first solder resist layer.

16. The semiconductor device assembly of claim 12, wherein:
the first resin encapsulation layer includes a printed resin layer; and
the second resin encapsulation layer includes a solder resist layer.

17. A method of producing a semiconductor device assembly, the method comprising:
coupling a semiconductor die with a base, the semiconductor die having a back side and a front side, the back side being coupled with the base, the front side including active circuitry;
forming a first resin encapsulation layer on, at least, a first portion of the front side of the semiconductor die, the first resin encapsulation layer being patterned to define a first opening that exposes a second portion of the front side of the semiconductor die through the first resin encapsulation layer;
forming a signal distribution structure on the first resin encapsulation layer, and in the first opening, such that the signal distribution structure is electrically coupled with the front side of the semiconductor die; and
forming a second resin encapsulation layer on, at least, a first portion of the signal distribution structure, the second resin encapsulation layer being patterned to define a second opening that exposes a second portion of the signal distribution structure.

18. The method of claim 17, wherein the semiconductor die is a first semiconductor die, the method further comprising:
coupling a second semiconductor die with the base, the signal distribution structure electrically coupling the active circuitry of the first semiconductor die with active circuitry included in the second semiconductor die.

19. The method of claim 17, wherein:
forming the first resin encapsulation layer includes forming a first solder resist layer; and
forming the second resin encapsulation layer includes forming a second solder resist layer.

20. The method of claim 17, wherein:
forming the first resin encapsulation layer includes forming a printed resin layer; and
forming the second resin encapsulation layer includes forming a solder resist layer.
